(19) United States
(12) Patent Application Publication
(10) Pub. No.: US 2014/0141177 A1
(43) Pub. Date: May 22, 2014

(54) MANUFACTURING METHOD OF DEPOSITION MATERIAL, MANUFACTURING APPARATUS OF DEPOSITION MATERIAL, ELECTRON BEAM IRRADIATION DEPOSITION METHOD AND DEPOSITION MATERIAL FOR ELECTRON BEAM IRRADIATION DEPOSITION

(71) Applicant: Sony Corporation, Tokyo (JP)

(72) Inventors: Go Sudo, Kanagawa (JP); Kenji Katori, Kanagawa (JP); Hayato Hommura, Kanagawa (JP)

(73) Assignee: Sony Corporation, Tokyo (JP)

(21) Appl. No.: 14/073,376

(22) Filed: Nov. 6, 2013

(30) Foreign Application Priority Data
Nov. 20, 2012 (JP) 2012-253869

(51) Int. Cl. C23C 16/48; C01B 33/113; B05D 1/18

(52) U.S. Cl. CPC C23C 16/487; B05D 1/18; C01B 33/113
USPC 427/596; 427/212; 118/58; 423/325

(57) ABSTRACT

There is provided a manufacturing method of a deposition material, including immersing at least one kind of powder in liquid, and after the immersing, vaporizing the liquid to solidify the powder as a deposition material for electron beam irradiation deposition.

### CROSS REFERENCE TO RELATED APPLICATIONS

This application claims the benefit of Japanese Priority Patent Application JP 2012-253869 filed Nov. 20, 2012, the entire contents of which are incorporated herein by reference.

### BACKGROUND

The present disclosure relates to a manufacturing method of a deposition material and a manufacturing apparatus of a deposition material, an electron beam irradiation deposition method using a deposition material, and a deposition material for electron beam irradiation deposition.

Electron beam irradiation deposition (hereinafter referred to as “EB deposition”) is known as one of deposition methods. The EB deposition is an industrially excellent deposition method in which the deposition rate is fast and the wear of the crucible which a deposition material is put into is relatively small. In the EB deposition, a deposition material (vaporization material) is irradiated with electron beams at a vacuum pressure to be melted and vaporized and the vaporized deposition material is deposited on the surface of a base material such as a substrate.

It is known that silicon monoxide (SiO), for example, is used for the deposition material in performing such EB deposition. Polymer films on whose surface silicon monoxide, for example, is deposited are known to be materials for packaging excellent in gas barrier property and have been spreading as packaging materials.

Silicon monoxide as the deposition material employs feed stock material that is deposited on a substrate such as a stainless steel plate. Japanese Patent Laid-Open No. 2002-194535 discloses an apparatus manufacturing silicon monoxide as a deposition material by means of deposition of feed stock.

### SUMMARY

The reason for using silicon monoxide that is deposited on the surface of a substrate in performing EB deposition is because it is difficult to use powdered deposition material for EB deposition. Powdered material scatters due to repulsion force caused by charge upon irradiation with electron beams for EB deposition. Due to this, the powdered material does not undergo melting or vaporization that is expected for the deposition, even under the irradiation with electron beams. In addition, existing deposition materials for EB deposition employ feed stock material that is deposited on a substrate, for example.

However, the process of performing deposition operation to obtain silicon monoxide that is deposited on a substrate is tedious operation and the material for deposition is exceedingly expensive, these being problematic.

It is desirable to provide a manufacturing method of a deposition material and a manufacturing apparatus of a deposition material, an electron beam irradiation deposition method using a deposition material obtained by the manufacturing method, and a deposition material for electron beam irradiation deposition, affording a deposition material for attaining EB deposition in a simple and cost-saving manner.

According to an embodiment of the present disclosure, there is provided a manufacturing method of a deposition material, including immersing at least one kind of powder in liquid, and after the immersing, vaporizing the liquid to solidify the powder as a deposition material for electron beam irradiation deposition.

According to an embodiment of the present disclosure, there is provided a manufacturing apparatus of a deposition material, including a container configured to immerse at least one kind of powder in liquid, and a vaporization processing part configured to vaporize the liquid in the container to solidify the powder as a deposition material for electron beam irradiation deposition.

Moreover, an electron beam irradiation deposition method according to an embodiment of the present disclosure includes: immersing at least one kind of powder in liquid; after the immersing, vaporizing the liquid to solidify the powder; and disposing the powder in a hearth of an electron beam irradiation deposition apparatus to perform electron beam irradiation deposition.

Moreover, a deposition material for electron beam irradiation deposition according to an embodiment of the present disclosure includes a solidified material obtained by vaporizing liquid from the liquid in which powder is immersed.

According to the present disclosure, powder as deposition material is solidified to afford a deposition material in a state appropriate for electron beam irradiation deposition. Namely, when powder immersed in liquid is solidified, capillary suction pressure, which generates due to surface tension among particles, generates. The capillary suction pressure allows the powder as deposition material to be solidified uniformly. The solidified powder does not scatter but is melted and vaporized under irradiation with electron beams in deposition.

According to the present disclosure, using a deposition material obtained by uniform solidification of powder due to capillary suction pressure enables to perform electron beam irradiation deposition excellently. Namely, since the powder is solidified a deposition material under irradiation with electron beams for electron beam irradiation deposition does not scatter but is vaporized, enabling excellent electron beam irradiation.

### BRIEF DESCRIPTION OF THE DRAWINGS

FIG. 1(a), FIG. 1(b) and FIG. 1(c) are diagrams illustrating a manufacturing process of a deposition material according to an example of a first embodiment of the present disclosure;

FIG. 2 is a diagram illustrating a principle of solidification according to the example of the first embodiment of the present disclosure;

FIG. 3 is a characteristics diagram representing relationship between water surface curvature radius and capillary tension according to the example of the first embodiment of the present disclosure;

FIG. 4 is a configuration diagram illustrating a deposition apparatus according to an example of a first embodiment of the present disclosure;

FIG. 5 is a diagram illustrating a manufacturing process of a deposition material according to an example of a second embodiment of the present disclosure;

FIG. 6 is a diagram illustrating the manufacturing process of a deposition material according to the example of the second embodiment of the present disclosure;

FIG. 7 is a diagram illustrating a deposition apparatus according to an example of a third embodiment of the present disclosure; and

FIG. 8 is a diagram illustrating a manufacturing process by a deposition apparatus in an example according to the third embodiment of the present disclosure.

### DETAILED DESCRIPTION OF THE EMBODIMENT(S)

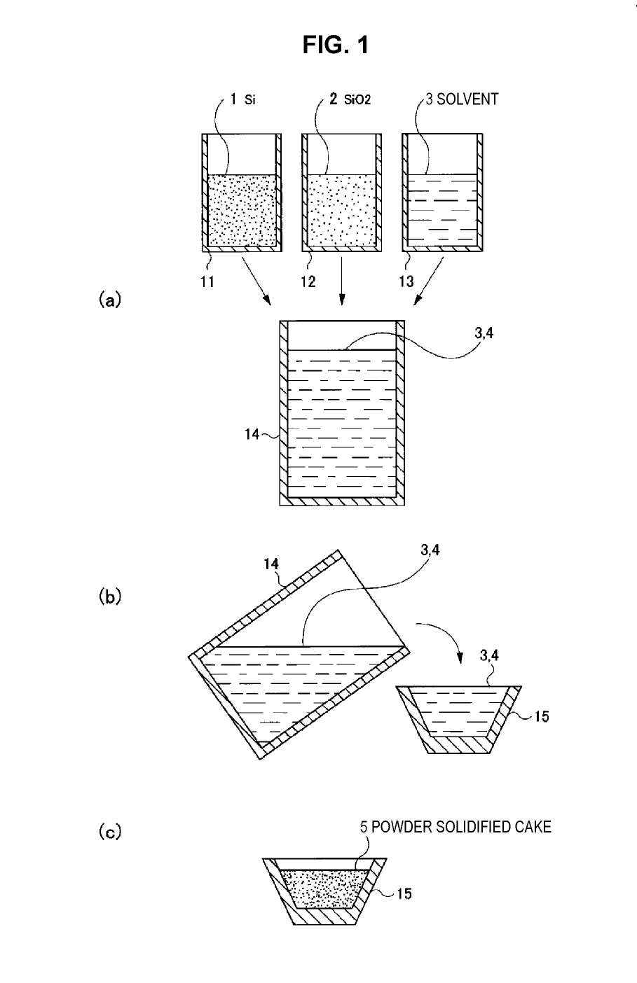

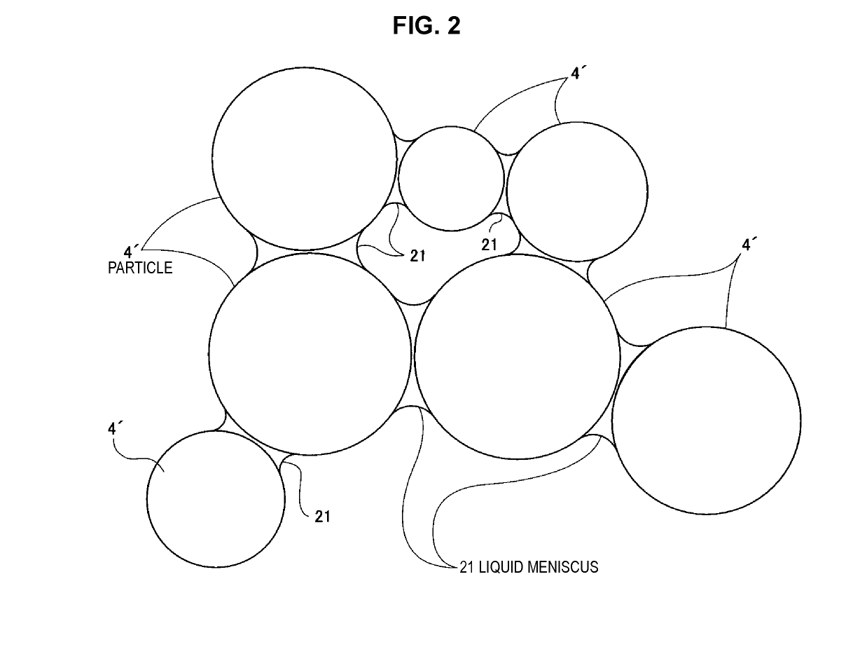

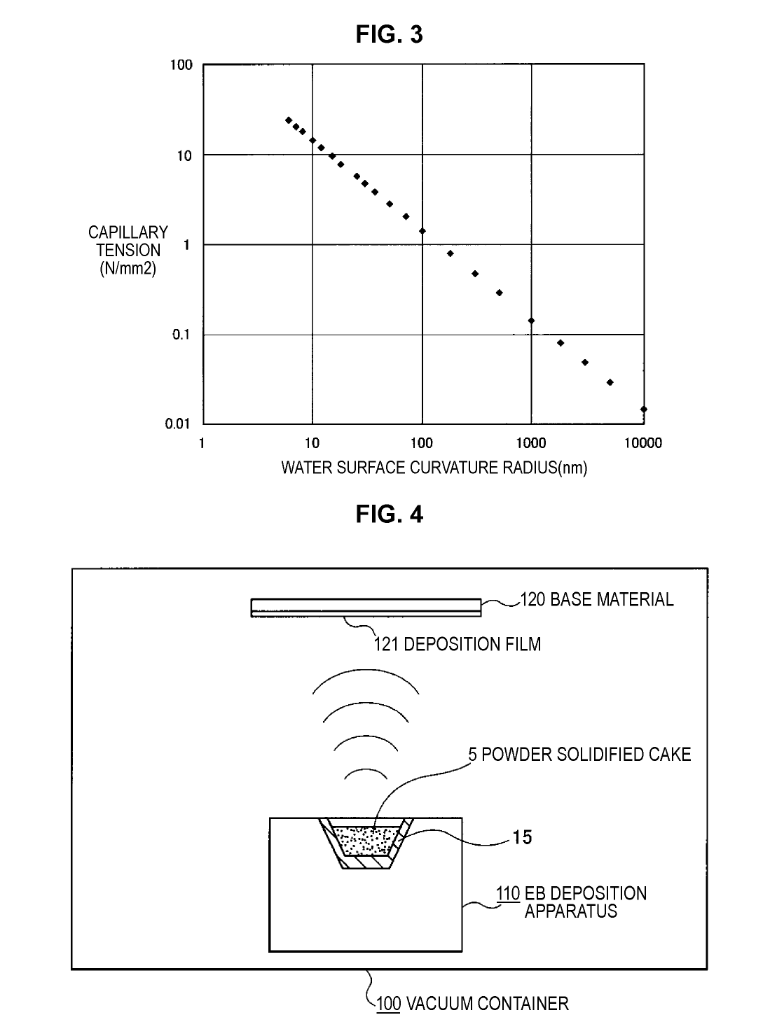

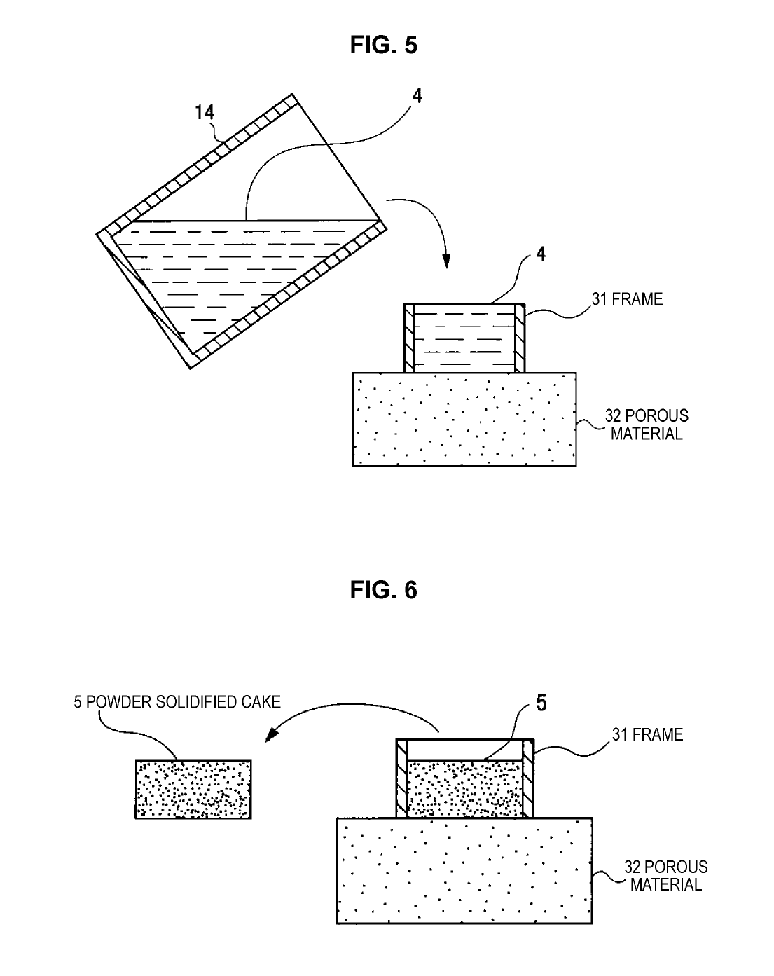

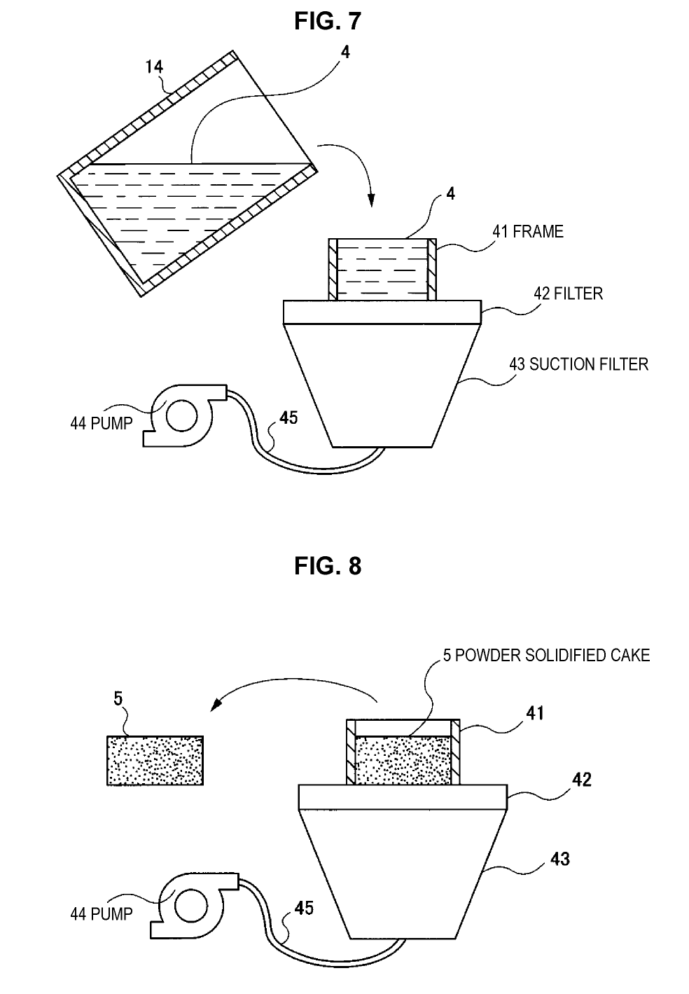

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted. The description is made in the following order.
1. First Embodiment
   1-1. Manufacturing Process of Deposition Material (FIG. 1(a), FIG. 1(b) and FIG. 1(c))
   1-2. Explanation of Caking State of Deposition Material (FIG. 2 and FIG. 3)
   1-3. Exemplary Configuration of Deposition Apparatus (FIG. 4)
2. Second Embodiment
   2-1. Manufacturing Process of Deposition Material (FIG. 5 and FIG. 6)
3. Third Embodiment
   3-1. Manufacturing Process and Manufacturing Apparatus of Deposition Material (FIG. 7 and FIG. 8)
4. Variations

### 1. First Embodiment

[1-1. Manufacturing Process of Deposition Material]

An example according to a first embodiment of the present disclosure is described with reference to FIG. 1(a), FIG. 1(b) and FIG. 1(c) to FIG. 4. FIG. 1(a), FIG. 1(b) and FIG. 1(c) are diagrams illustrating a manufacturing process of a deposition material according to an example of the first embodiment. In an example according to the first embodiment of the present disclosure, a process of obtaining silicon monoxide (SiO) as a deposition material is described. First, as illustrated in FIG. 1(a), a powder 1 of silicon (Si) and a powder 2 of silicon dioxide (SiO₂) are prepared as feed stock. Each of the powders 1 and 2 has, for example, approximately 60 to 70 μm of mean particle diameter to be used. Moreover, in the manufacturing process, a solvent 3, which is liquid, is prepared. In the example illustrated in FIG. 1(a), the powder 1 of silicon is put into a container 11, the powder 2 of silicon dioxide is put into a container 12 and the solvent 3 is put into a container 13. Liquid with strong surface tension is preferable as the solvent 3. In the example, pure water is used for the solvent 3.

Then, as illustrated in FIG. 1(a), in the manufacturing process, a container 14 for obtaining a mixed powder is prepared. Then, the powder 1 of silicon which powder is put into the container 11 and the powder 2 of silicon dioxide which powder is put into the container 12 are poured into the container 14 to be mixed and to afford a mixed powder 4. When mixing the powder 1 of silicon and the powder 2 of silicon dioxide, they are mixed in 1:1 or 2:1 of molar ratio.

Furthermore, the solvent 3 which is pure water is put into the container 14. At this stage, the solvent 3 at whose amount a weight ratio between the mixed powder 4 and the solvent 3 is 2:1 is put thereinto to immerse the mixed powder 4 in the solvent 3.

When the powders 1 and 2 and the solvent 3 are put into the container 14, for example, ultrasonic waves are applied to the container 14. Applying ultrasonic waves as above allows the dispersion state of the solvent 3 to be uniform and the mixing state of the powders 1 and 2 to be uniform in the container 14.

Then, as illustrated in FIG. 1(b), in the manufacturing process, the mixed powder 4 immersed in the solvent 3 is put into a hearth 15 for EB deposition. The hearth 15 is made, for example, of copper. In the example illustrated in FIG. 1(b), the hearth 15 is trapezoidal whose shape is gradually expanding from the bottom face toward the upper face.

Next, in the manufacturing process, as illustrated in FIG. 1(c), the inside of the hearth 15 is desiccated. At this stage, for example, the inside of the hearth 15 undergoes air drying at ambient temperature under ambient pressure to remove the solvent 3. For example, the hearth 15 is left in an environment of ambient temperature and ambient pressure for approximately 2 days to undergo air drying until the solvent 3 disappears.

When desiccating the inside of the hearth 15 heating or the like may be performed. The desiccation vaporizes the solvent 3 to afford a powder solidified cake 5 composed of the mixed powder.

[1-2. Explanation of Caking State of Deposition Material]

The powder solidified cake 5 obtained by the process illustrated in FIG. 1(a), FIG. 1(b) and FIG. 1(c) is being solidified at a strength appropriate as a deposition material for EB deposition, this explained herein.

FIG. 2 is an enlarged view illustrating vaporization of the solvent 3 dispersed in the mixed powder 4.

FIG. 2 illustrates a state where the volume of the solvent 3 is smaller than the volume of spacings among individual particles 4′ of the mixed powder 4 in the midway of the solvent 3 undergoing vaporization.

In the state illustrated in FIG. 2, a meniscus 21 in which a surface of the solvent 3 is a curved surface is formed. The curvature of the meniscus 21 gradually decreases as the volume of the solvent 3 decreases. At this stage, due to the surface tension of the solvent 3, capillary suction pressure ΔP generates as indicated in equation (1) below.

ΔP=2γ/r (1)

In equation (1), r designates a curvature radius of solvent and y designates surface tension of the solvent. The individual particles 4′ in the mixed powder 4 are solidified with sufficient strength due to the effect of the capillary suction pressure ΔP.

FIG. 3 is a diagram illustrating relationship between a liquid curvature radius of water, which is used for the solvent 3, and capillary suction pressure. The surface tension of water at 20° C. is 72.75 mN/m and force not less than 10 N/mm² is exerted between particles immediately before the water completely vaporizes.

The force exerted between particles is applied to all of the particles regardless to positions, sizes or shapes of the particles. Due to this, all of the particles in the mixed powder 4 are solidified uniformly and efficiently. For example, when a mixed powder is solidified by applying pressure using a pressing machine, solidification uniform for all of the particles as above is difficult.

[1-3. Exemplary Configuration of Deposition Apparatus]

FIG. 4 is a diagram illustrating EB deposition using the powder solidified cake 5 obtained according to the manufacturing process illustrated in FIG. 1(a), FIG. 1(b) and FIG. 1(c).

An EB deposition apparatus 110 is disposed in the vacuum container 100. The hearth 15 into which the powder solidified cake 5 which is a deposition material is put is disposed in the EB deposition apparatus 110. Then, a base material 120 on which silicon monoxide is deposited is disposed at a position where it opposes to the hearth 15 of the EB deposition apparatus 110.

In such a state, when the EB deposition apparatus 110 irradiates the powder solidified cake 5 in the hearth 15 with electron beams, the particles in the powder solidified cake 5 are melted and evaporated. Then, a deposited film 121 made of silicon monoxide is formed on the surface of the base material 120.

As above, since the particles in the powder solidified cake 5 are uniformly solidified in performing the EB deposition, the particles do not scatter under the irradiation of electron beams and the deposited film 121 can be obtained excellently.

Table 1 below presents measurements of the average valence number of the deposited film 121 having obtained by the EB deposition using photoelectron spectroscopy apparatus (XPS: X-ray Photoelectron Spectroscopy).

TABLE 1
Mixing ratio of powder of deposition source and valence number of Si
in deposited material

| | | | | | | average |
|---|---|---|---|---|---|---|
| | 0 | +1 | +2 | +3 | +4 | valence |
| Si:SiO2 | valence | valence | valence | valence | valence | number |
| 1:1 | 17% | 11% | 17% | 25% | 30% | +2.4 |
| 2:1 | 17% | 11% | 17% | 25% | 30% | +2.4 |

Table 1 above presents two examples of the mixing ratios of silicon (Si) and silicon dioxide (SiO₂) being 1:1 and 2:1. In these examples, for any mixing ratio, the average valence number is +2.4. The average valence number of +2.4 is approximately close to +2 which is the valence number of silicon monoxide.

Silicon, silicon dioxide and silicon monoxide have boiling points of 2360° C., 2230° C. and 1880° C., respectively. In deposition, silicon and silicon dioxide undergo contact reaction and reactive deposition takes place, forming silicon monoxide having a valence number close to +2.

In addition, in any case of the mixing ratios of silicon and silicon dioxide being 1:1 and 2:1, the valence number does not present difference, they forming silicon monoxide.

### 2. Second Embodiment

[2-1. Manufacturing Process of Deposition Material]

Next, an example according to a second embodiment of the present disclosure is described with reference to FIG. 5 to FIG. 6.

In the example according to the second embodiment, processing of desiccating the mixed powder 4 immersed in the solvent 3 is different from one in the example according to the first embodiment.

Processing until obtaining the mixed powder 4 in which the solvent 3 composed of pure water is dispersed is same as the processing illustrated in FIG. 1(a) in the example according to the first embodiment. In the example, when obtaining the mixed powder 4 in which the solvent 3 is dispersed, for example, it is preferable to apply ultrasonic waves uniformly to disperse the powder 1 of silicon and the powder 2 of silicon dioxide while uniformly dispersing the solvent 3.

FIG. 5 and FIG. 6 are diagrams illustrating a process in desiccation.

As illustrated in FIG. 5, in the manufacturing process, a frame 31 and a porous material 32 are used and the frame 31 is disposed on the porous material 32. The frame 31 has a shape only having a side face and not having a bottom face. The frame 31 is formed, for example, of paper. The porous material 32 is sponge-like in which many fine through-holes are formed not to pass the particles of the mixed powder 4 therethrough.

The mixed powder 4 in which the solvent 3 is dispersed is put into the frame 31 placed on the porous material 32. At this stage, the solvent 3 in the frame 31 is sucked downward due to capillary pressure of the porous material 32.

Due to this, after it is left for some time period, the powder solidified cake 5 is left in the frame 31 as illustrated in FIG. 6. As above, in the state where the powder is solidified, the porous material 32 is separated from the powder solidified cake 5. Then, after the powder solidified cake 5 thus obtained is taken out of the frame 31, it undergoes air drying still at ambient temperature under ambient pressure.

The desiccated powder solidified cake 5 is a deposition material for EB deposition. Namely, the desiccated powder solidified cake 5 is mounted on the hearth 15 of the EB deposition apparatus 110 illustrated in FIG. 4 as a deposition material similarly to one in the example according to the first embodiment, and EB deposition is performed. A deposited film obtained by the EB deposition is equivalent to the deposited film obtained in the example according to the first embodiment.

In the example according to the second embodiment, since the powder solidified cake 5 is desiccated after the solvent 3 therein is sucked using the porous material 32, the time period for air drying can be reduced compared with the example according to the first embodiment.

### 3. Third Embodiment

[3-1. Manufacturing Process and Manufacturing Apparatus of Deposition Material]

Next, an example according to a third embodiment of the present disclosure is described with reference to FIG. 7 to FIG. 8.

The example according to the third embodiment is to make the process for obtaining the powder solidified cake 5 further more efficient.

Also in the example according to the third embodiment, processing until obtaining the mixed powder 4 in which the solvent 3 is dispersed is same as the processing illustrated in FIG. 1(a) in the example according to the first embodiment. When obtaining the mixed powder 4 in which the solvent 3 is dispersed, it is also preferable to apply ultrasonic waves, this being same as in the example according to the first embodiment.

FIG. 7 and FIG. 8 are diagrams illustrating an apparatus configuration and a process in desiccation.

As illustrated in FIG. 7, a frame 41 is disposed on a filter 42. The frame 41 has a shape only having a side face and not having a bottom face and is formed, for example, of paper. The filter 42 is a membrane-like member formed of material which does not pass the particles of the mixed powder 4 therethrough but passes the solvent 3 therethrough.

Moreover, a suction filter 43 is disposed beneath the filter 42. The suction filter 43 is connected to a pump 44 via a tube 45 and action of the pump 44 allows the solvent 3 to be sucked.

After such suction operation by the suction filter 43, as illustrated in FIG. 8, the powder solidified cake 5 is left in the frame 41. After the powder solidified cake 5 thus obtained is taken out of the frame 41, it undergoes air drying still at ambient temperature under ambient pressure as necessary. When the powder solidified cake 5 is sufficiently desiccated in the suction operation using the suction filter 43, processing of performing air drying is unnecessary.

The powder solidified cake 5 thus desiccated is a deposition material for EB deposition. Namely, the desiccated powder solidified cake 5 is mounted on the hearth 15 of the EB deposition apparatus 110 illustrated in FIG. 4 as a deposition material, and thereby, EB deposition is performed. A deposited film obtained by the EB deposition is equivalent to the deposited films obtained in the examples according to the first and second embodiments.

In the example according to the third embodiment, since the solvent 3 is sucked using the suction filter 43 the time period for desiccation can be further reduced.

### 4. Variations

In each of the above-mentioned embodiments, an example is described in which a mixed powder obtained by mixing a powder of silicon and a powder of silicon dioxide is immersed in a solvent to form a deposition material for obtaining silicon monoxide. On the contrary, one obtained by solidifying other powder may be used as a deposition material. Examples can include one using two kinds of powder. A deposition material may be obtained by solidifying powder to be composed of one kind of powder.

Moreover, the particle diameters and mixing ratios of silicon and silicon dioxide represented in the above-mentioned embodiments are only exemplary and other particle diameters and mixing ratios may be applied.

Moreover, in each of the above-mentioned embodiments, powder which is immersed in a solvent is put into a hearth or a frame as a solvent vaporization processing part, and the powder is solidified by air drying and/or suction of the solvent. On the contrary, the solvent vaporization processing part may perform heating processing or the like on the powder which is immersed in the solvent, reducing the time period for desiccation.

Moreover, in each of the above-mentioned embodiments, pure water is used for a solvent. Surfactant, binder or the like may be added to the pure water as a solvent as necessary. Moreover, an organic solvent may be used for a solvent. Furthermore, thermal processing may be performed on the solvent depending on the additive.

Moreover, an example of the EB deposition apparatus is presented which forms the deposited film 121 on the plate-like base material 120, as illustrated in FIG. 4. On the contrary, a deposition material according to an embodiment of the present disclosure may be applied to formation of a deposited film on the surfaces of materials with other shapes.

Moreover, in the example according to each of the above-mentioned embodiments, one obtained by mixing two kinds of powders (a powder of silicon and a powder of silicon dioxide) is used as a deposition material and reactive deposition of obtaining a deposited film of silicon monoxide is performed.

On the contrary, solidified cakes may be formed which are obtained by individually solidifying a powder of silicon and a powder of silicon dioxide as deposition materials. In this case, in order to obtain a deposited film of silicon monoxide, the two solidified cakes are melted and vaporized simultaneously in EB deposition to perform codeposition.

It should be understood by those skilled in the art that various modifications, combinations, sub-combinations and alterations may occur depending on design requirements and other factors insofar as they are within the scope of the appended claims or the equivalents thereof.

Additionally, the present technology may also be configured as below.
(1)
1. A manufacturing method of a deposition material, including:

immersing at least one kind of powder in liquid; and

after the immersing, vaporizing the liquid to solidify the powder as a deposition material for electron beam irradiation deposition.
(2)
The manufacturing method of a deposition material according to (1),

wherein the liquid in which the powder is immersed is poured into a hearth for the electron beam irradiation deposition and the liquid is vaporized.
(3)
The manufacturing method of a deposition material according to (1) or (2),

wherein the liquid in which the powder is immersed is placed on a porous material, and the liquid is vaporized while being sucked, and

wherein the deposition material is obtained by separating the porous material after the liquid is vaporized.
(4)
The manufacturing method of a deposition material according to any one of (1) to (3),

wherein two or more kinds of powder are used as the powder immersed in the liquid, and

wherein a mixing ratio of the two or more kinds of powder is configured to obtain a deposition material for reactive deposition.
(5)
A manufacturing apparatus of a deposition material, including:

a container configured to immerse at least one kind of powder in liquid; and

a vaporization processing part configured to vaporize the liquid in the container to solidify the powder as a deposition material for electron beam irradiation deposition.
(6)
The manufacturing apparatus of a deposition material according to (5),

wherein the container is a hearth for electron beam irradiation deposition.
(7)
The manufacturing apparatus of a deposition material according to (5),

wherein the vaporization processing part includes a porous material disposed on a bottom face of the container.
(8)
The manufacturing apparatus of a deposition material according to (5),

wherein the vaporization processing part includes a suction pump configured to suck the liquid in the container.
(9)
An electron beam irradiation deposition method including:

immersing at least one kind of powder in liquid;

after the immersing, vaporizing the liquid to solidify the powder; and

disposing the powder in an electron beam irradiation deposition apparatus to perform electron beam irradiation deposition.
(10)
A deposition material for electron beam irradiation deposition, including:

a solidified material obtained by vaporizing liquid from the liquid in which powder is immersed.

What is claimed is:

1. A manufacturing method of a deposition material, comprising:
immersing at least one kind of powder in liquid; and
after the immersing, vaporizing the liquid to solidify the powder as a deposition material for electron beam irradiation deposition.

2. The manufacturing method of a deposition material according to claim 1,
wherein the liquid in which the powder is immersed is poured into a hearth for the electron beam irradiation deposition and the liquid is vaporized.

3. The manufacturing method of a deposition material according to claim 1,
wherein the liquid in which the powder is immersed is placed on a porous material, and the liquid is vaporized while being sucked, and
wherein the deposition material is obtained by separating the porous material after the liquid is vaporized.

4. The manufacturing method of a deposition material according to claim 1,
wherein two or more kinds of powder are used as the powder immersed in the liquid, and
wherein a mixing ratio of the two or more kinds of powder is configured to obtain a deposition material for reactive deposition.

5. A manufacturing apparatus of a deposition material, comprising:
a container configured to immerse at least one kind of powder in liquid; and
a vaporization processing part configured to vaporize the liquid in the container to solidify the powder as a deposition material for electron beam irradiation deposition.

6. The manufacturing apparatus of a deposition material according to claim 5,
wherein the container is a hearth for electron beam irradiation deposition.

7. The manufacturing apparatus of a deposition material according to claim 5,
wherein the vaporization processing part includes a porous material disposed on a bottom face of the container.

8. The manufacturing apparatus of a deposition material according to claim 5,
wherein the vaporization processing part includes a suction pump configured to suck the liquid in the container.

9. An electron beam irradiation deposition method comprising:
immersing at least one kind of powder in liquid;
after the immersing, vaporizing the liquid to solidify the powder; and
disposing the powder in an electron beam irradiation deposition apparatus to perform electron beam irradiation deposition.

10. A deposition material for electron beam irradiation deposition, comprising:
a solidified material obtained by vaporizing liquid from the liquid in which powder is immersed.
